(19) United States
(12) Patent Application Publication
(10) Pub. No.: US 2006/0035466 A1
(43) Pub. Date: Feb. 16, 2006

(54) Method for manufacturing plasma display panels

(75) Inventors: Masahiro Watabe, Kawasaki (JP); Syuma Eifuku, Kawasaki (JP); Tatsuya Torinari, Kawasaki (JP); Tetsuro Kawakita, Kawasaki (JP); Hideki Harada, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU HITACHI PLASMA DISPLAY LIMITED, Kawasaki (JP)

(21) Appl. No.: 11/094,838

(22) Filed: Mar. 31, 2005

(30) Foreign Application Priority Data
Aug. 10, 2004 (JP) 2004-233228

(51) Int. Cl. H01L 21/20

(52) U.S. Cl. 438/694

(57) ABSTRACT

A method for manufacturing a plasma display panel including a dielectric layer that is formed by a vapor deposition method and covers electrodes except their terminal portions, includes the steps of depositing a dielectric on a substrate on which each of the electrodes having a terminal portion at an end is arranged by a vapor deposition method so that the dielectric forms a layer for covering the electrodes over the entire length thereof, and removing a portion of the layer formed by the vapor deposition method that covers the terminal portions of the electrodes by a polishing method in which a polishing rate of the portion is larger than that of the terminal portion or by a dry etching method.

### BACKGROUND OF THE INVENTION

1. Field of the Invention

The present invention relates to a method for manufacturing a plasma display panel.

2. Description of the Prior Art

An AC type plasma display panel has a dielectric layer for covering display electrodes. The dielectric layer is an element having a large area over the entire screen. The dielectric layer is electrostatically charged with so-called wall charge by gas discharge, and the wall charge is utilized for a drive control so that cells within the screen are selectively driven to emit light.

In general, the dielectric layer is made of a low melting point glass and formed by a thick-film method in which a glass frit layer is burned. In the process of burning, the entire of the display electrodes is covered with a glass frit layer, which prevents the display electrodes from oxidizing. After the burning process and a laminating process of a substrate on which the dielectric layer is formed with another substrate, terminal portions of the display electrodes are exposed by removing an end portion of the dielectric layer so that the terminal portions can be connected to a driving circuit board.

A preferable method for partially removing the dielectric layer made of a low melting point glass is a wet etching. When an edge portion of a pair of combined substrates is dipped in an etchant bath, terminal portions of the display electrodes can be exposed efficiently. A typical etchant for a low melting point glass is a nitric acid.

On the other hand, a vapor deposition method (or a vapor-phase growth method) has become a focus of attention recently as a method for forming a dielectric layer. Japanese unexamined patent publication No. 2000-21304 describes forming a dielectric layer made of silicon dioxide or organic silicon oxide by plasma CVD (Chemical Vapor Deposition) that is one type of chemical vapor deposition method. According to the vapor deposition method, a thin dielectric layer having a uniform thickness can be obtained. In addition, a dielectric layer made of a material having a small relative dielectric constant that is advantageous for reducing capacitance between electrodes can be formed at a lower temperature than the thick-film method.

However, when forming a dielectric layer by the vapor deposition method, it is difficult to expose the terminal portions of the display electrodes without lowering productivity.

There are two methods of exposing the terminal portions of the display electrodes. One of them is a method of masking the substrate on which the electrodes are arranged by placing a mask on the terminal portions of the display electrodes when the dielectric layer is deposited. Another method is removing the dielectric layer in part after the dielectric layer is deposited so as to cover the entire electrodes.

However, there is a high possibility in the masking process that the dielectric layer deposited on the substrate and the dielectric layer deposited on the mask become continuous as one layer. If the substrate and the mask are combined via the dielectric, the dielectric layer may be damaged when the mask is removed from the substrate after the deposition, resulting in a drop of yield. In addition, usage of the mask lowers operating efficiency of a deposition system when manufacturing plural types of plasma display panels having different dimensions. It is because that sufficient time is required for security of work when exchanging the mask so that temperature inside the deposition system decreases.

In addition, if the wet etching method is used for removing the dielectric layer in part similarly to the conventional method, there is a high possibility that the terminal portions of the electrodes are destroyed. Namely, there is no suitable etchant that dissolves the dielectric layer formed by the vapor deposition method and does not dissolve the electrodes selectively with good cost efficiency and good safety. For example, hydrofluoric acid can dissolve silicon dioxide, but it does not have selectivity to copper and chrome that are typical materials of the terminal portions of the electrodes. Therefore, if hydrofluoric acid is used for etching the dielectric layer made of silicon dioxide, a very precise control of etching is required so that dissolve of the terminal portions of the electrodes becomes the minimum.

### SUMMARY OF THE INVENTION

An object of the present invention is to improve productivity of plasma display panels having a dielectric layer that is formed by a vapor deposition method for covering electrodes except terminal portions thereof.

A method according to the present invention includes the steps of forming a dielectric layer that covers the electrodes over the entire length thereof by a vapor deposition method on a substrate on which electrodes having terminal portions at their ends are arranged, and removing a portion of the dielectric layer formed by the vapor deposition method that covers the terminal portions of the electrodes by a polishing method in which a polishing rate of the portion is larger than that of the terminal portion or by a dry etching method. A chemical mechanical polishing method is a preferable polishing method.

Usage of both a mechanical polishing method and the chemical mechanical polishing method enables shortening of a process time of the polishing step. Prior to the polishing step by the chemical mechanical polishing method that has selectivity to the terminal portions and the dielectric layer, a portion to be polished of the dielectric layer may be thinned by the mechanical polishing method that has a higher polishing rate than the chemical mechanical polishing method. Thus, the terminal portions may be exposed in a shorter time than the case where only the chemical mechanical polishing method is used.

According to that constitution, productivity can be improved in manufacturing a plasma display panel that includes a dielectric layer that is formed by a vapor deposition method and covers electrodes except their terminal portions.

### BRIEF DESCRIPTION OF THE DRAWINGS

FIG. 1 shows an overall structure of a plasma display panel.

FIG. 2 shows a cross sectional structure of the plasma display panel.

FIG. 3 is a schematic diagram of an electrode matrix.

FIG. 4 shows an example of a cell structure of the plasma display panel.

FIG. 5 shows a pattern of display electrodes.

FIGS. 6(A)-6(D) show a first example of a manufacturing process of the plasma display panel.

FIG. 7 shows a ground area of the dielectric.

FIGS. 8(A)-8(F) show a second example of the manufacturing process of the plasma display panel.

FIGS. 9(A)-9(D) show a third example of the manufacturing process of the plasma display panel.

FIGS. 10(A)-10(D) show a fourth example of the manufacturing process of the plasma display panel.

### DESCRIPTION OF THE PREFERRED EMBODIMENTS

Hereinafter, the present invention will be explained more in detail with reference to embodiments and drawings.

### Embodiment of the Invention

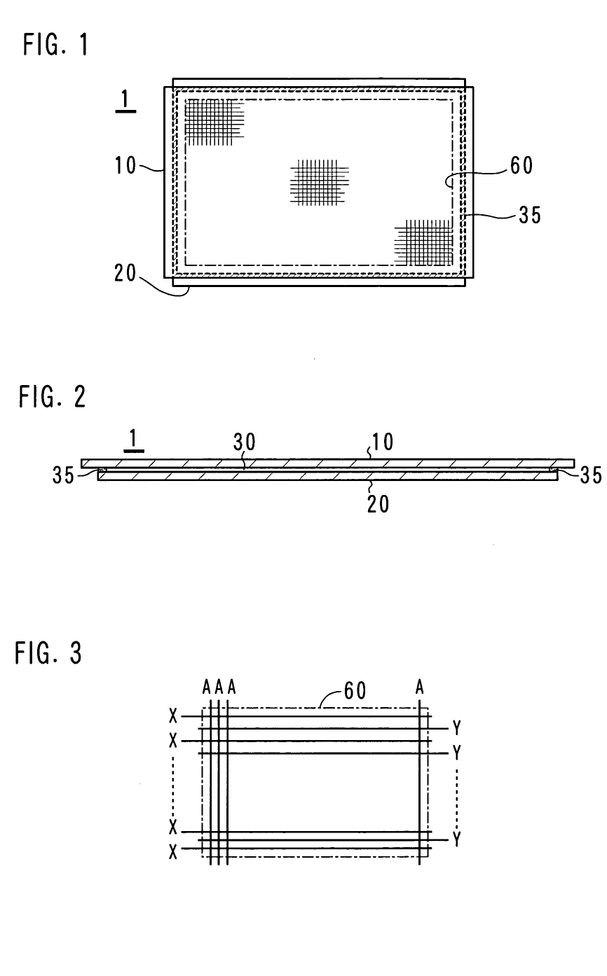

FIG. 1 shows an overall structure of a plasma display panel, and FIG. 2 shows a cross sectional structure of the plasma display panel. The plasma display panel 1 includes a front plate 10, a back plate 20, and a screen 60 in which discharge cells are arranged in a matrix. Each of the front plate 10 and the back plate 20 is a structural body including a glass substrate that is larger than the screen 60 and has a thickness of approximately 3 mm, and electrodes and other elements fixed to the glass substrate. The front plate 10 and the back plate 20 are positioned so that they are opposed to each other like overlapped layers, and they are glued to each other via a seal member 35 having a rectangular frame-like shape in a plan view at the peripheral portions thereof. An inner space 30 sealed by the front plate 10, the back plate 20 and the seal member 35 is filled with a discharge gas that is a mixture of neon and xenon. If the screen 60 has a diagonal size of 42 inches for example, the plasma display panel 1 has a dimension of approximately 994 mm×585 mm. A thickness of the inner space 30 (i.e., a depth in the horizontal direction) has a value within the range of 100-200 μm.

The front plate 10 protrudes from each end of the back plate 20 by approximately 5 mm in the horizontal direction in FIG. 1, while the back plate 20 protrudes from each end of the front plate 10 by approximately 5 mm in the vertical direction in FIG. 1. These protruding end portions of the front plate 10 and the back plate 20 are connected to flexible circuit boards for electric connection to a drive unit.

FIG. 3 is a schematic diagram of an electrode matrix. The electrode matrix is made up of display electrodes X and Y that are row electrodes and address electrodes that are column electrodes. The display electrodes X and the display electrodes Y are arranged in parallel so that they are disposed alternately like X, Y, X, Y, . . . X, Y, X. A set of neighboring display electrode X and the display electrode Y constitute an electrode pair (an anode and a cathode) for generating display discharge in a surface discharge form. A total number of display electrodes X and display electrodes Y is the number of rows in the screen 60 plus one. The number of address electrodes is equal to the number of columns.

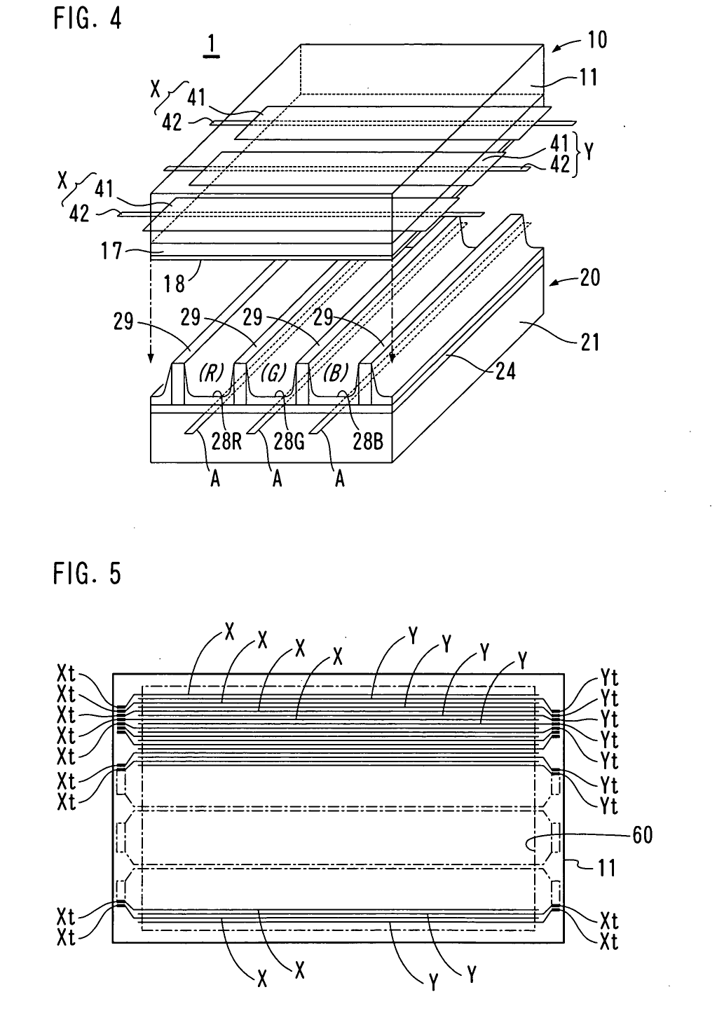

FIG. 4 shows an example of a cell structure of the plasma display panel. The front plate 10 and the back plate 20 are drawn separately for making the inner structure easily understood in FIG. 4.

The front plate 10 includes a glass substrate 11, the display electrodes X and Y, a dielectric layer 17 and a protection film 18. Each of the display electrodes X and Y is a lamination of a patterned transparent conductive film 41 and a metal film 42. The dielectric layer 17 and the protection film 18 cover the display electrodes X and Y so as to insulate them from the discharge gas.

The back plate 20 includes a glass substrate 21, address electrodes A, an insulator layer 24, a plurality of partitions 29 and fluorescent material layers 28R, 28G and 28B. The illustrated arrangement of the partitions 29 is a stripe pattern. Alphabetical letters R, G and B in parentheses in FIG. 4 indicate light emission colors of the fluorescent materials.

Next, the display electrodes X and Y having a close relationship to the present invention will be described in more detail.

FIG. 5 shows a pattern of the display electrodes. The display electrodes X and the display electrodes Y extend from the screen 60 to the vicinity of the rim of the glass substrate 11 and have terminal portions Xt and Yt for electric connection to the drive unit. As shown in FIG. 5, the terminal portions Xt of the display electrodes X are disposed at the left end side of the glass substrate 11, while the terminal portions Yt of the display electrodes Y are disposed at the right end side of the glass substrate 11. Since an arrangement pitch of the terminal portions Xt is different from an arrangement pitch of the display electrodes X on the screen 60, the left end portions of the display electrodes X (including the terminal portions Xt) are patterned in curved band-like shapes. Each of these curved portions is not the lamination of the patterned transparent conductive film 41 and the metal film 42 but is made up of only the metal film 42. In the same way, the right end portions of the display electrodes Y (including the terminal portions Yt) are patterned in curved band-like shapes, and each of these curved portions is made up of only the metal film 42.

The plasma display panel 1 having the structure described above is manufactured by the process that includes steps of making the front plate 10 and the back plate 20 separately, and then gluing them to each other. A mother glass having an area of twice the glass substrate 11 or more is used for making the front plate 10, and plural front plates 10 are made at the same time. In the same way, plural back plates 20 are made at the same time. The mother glass is divided prior to the gluing process, so that the divided front plate 10 and the divided back plate 20 are glued to each other.

In the manufacturing process of the front plate 10, the dielectric layer 17 is formed by a vapor deposition method. On this occasion, masking of the terminal portions Xt and Yt is not performed. After vapor deposition is completed, the deposition layer is removed in part so as to expose the terminal portions Xt and Yt as described in the following examples.

### EXAMPLE 1

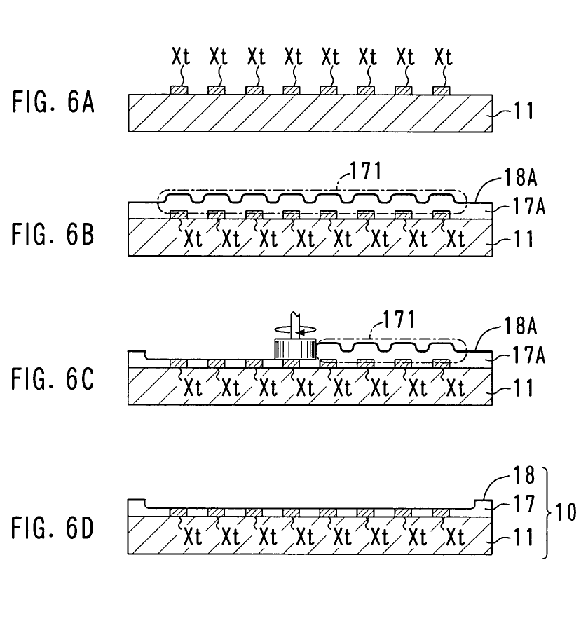

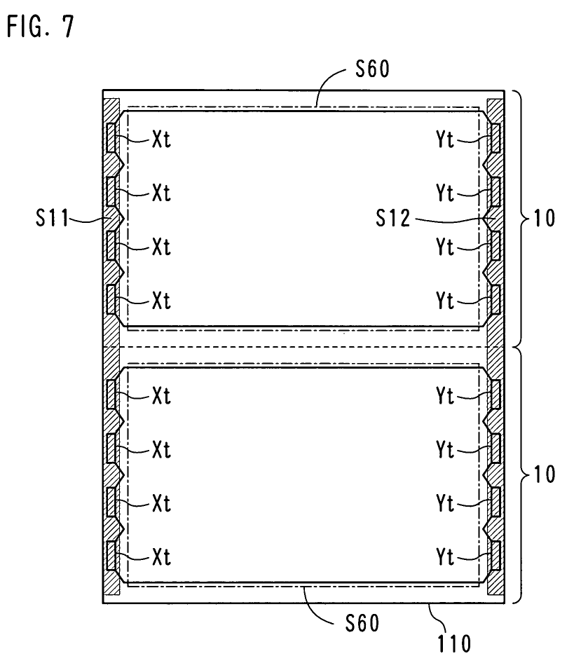

FIGS. 6(A)-6(D) show a first example of a manufacturing process of the plasma display panel, and FIG. 7 shows a ground area of the dielectric.

In the manufacturing process of the front plate 10, the above-mentioned display electrodes X and Y are formed in accordance with the following procedure. (1) A transparent conductive film made of tin oxide (NESA) or ITO having a thickness of approximately 5000 angstroms is formed on the surface of the glass substrate 11 (or on the surface of the mother glass, to be exact, and it is patterned by photolithography. (2) A metal film is formed on the glass substrate 11, and it is patterned by photolithography. A typical metal film is a three-layered film of chrome, copper and chrome, and a thickness thereof is approximately 3 μm. FIG. 6(A) schematically shows a cross sectional structure of the display electrodes X at the portions where the terminal portions Xt are disposed on the glass substrate 11 on which the display electrodes X and Y are formed.

After forming the display electrodes, the dielectric is glued to the glass substrate 11 so as to form a layer that covers the display electrodes over the entire length by the vapor deposition method. More specifically, silicon dioxide (SiO₂) is deposited by plasma CVD that is one type of the vapor deposition method so as to form a layer having a thickness of approximately 10 μm. An example of a deposition condition is as follows.
Type of device: parallel plate type
Source of gas: tetraethoxysilane (TEOS, Si(C₂H₅O)₄)
Reaction gas: oxygen (O₂)
Supplied gas flow: TEOS/800 SCCM, O₂/2000 SCCM
High frequency output: 1.5 kW
Substrate temperature: 350° C.
Degree of vacuum: 1.0 Toor

Other examples of the deposition condition are as follows.
Type of device: parallel plate type
Source of gas: SiH₄
Reaction gas: N₂O
Supplied gas flow: SiH₄/900 SCCM, N₂O/10000 SCCM
High frequency output: 2.0 kW
Substrate temperature: 400° C.
Degree of vacuum: 2.5 Toor
Type of device: parallel plate type
Source of gas: SiH₄
Reaction gas: CO₂
Supplied gas flow: SiH₄/900 SCCM, CO₂/20000 SCCM
High frequency output: 2.0 kW
Substrate temperature: 350° C.
Degree of vacuum: 3.5 Toor

FIG. 6(B) shows a state where a layer 17A made of silicon dioxide and a film 18A made of magnesia (MgO) that is a protection film material are formed. As a feature of film deposition by the vapor deposition method, the surface of the layer 17A has pits and projections corresponding to the surface contour of the substrate. Since a thickness of the film 18A is approximately 5000 angstroms that is very thin compared with the layer 17A, the layer 17A is substantially the only insulator that covers the terminal portions Xt and Yt (only the terminal portions Xt are shown in FIG. 6(B)).

FIG. 6(C) shows a step of removing an undesired portion of the layer 17A formed by the vapor deposition method, which corresponds to a portion 171 that covers the terminal portions Xt and the terminal portions Yt (not shown). In this example, the portion 171 is removed by a chemical mechanical polishing (CMP) method. A standard of polishing depth corresponds to an upper end portion of the layer 17A. Although FIG. 6(C) shows a single glass substrate 11, two glass substrates 11 within the mother glass are polished at the same time in reality. Object areas to be polished are two areas S11 and S12 at both sides of the area S60 corresponding to the screen on the mother glass 110 as shown in FIG. 7.

The chemical mechanical polishing step utilizes a device that rotates a moving member to which abrasive cloth is fixed for polishing. The following conditions were adopted for polishing, and a polishing rate was 300 nm/min.
Abrasive material: ceria (CeO₂, cerium oxide)
Rotation speed of the moving member: 50 rpm
Working pressure: 400 g/cm²

FIG. 6(D) shows the front plate 10 having the dielectric layer 17 that is processed so that the terminal portions Xt are exposed. This front plate 10 is put on the back plate 20 that is manufactured in another step, and they are glued to each other so that the plasma display panel 1 is completed.

### EXAMPLE 2

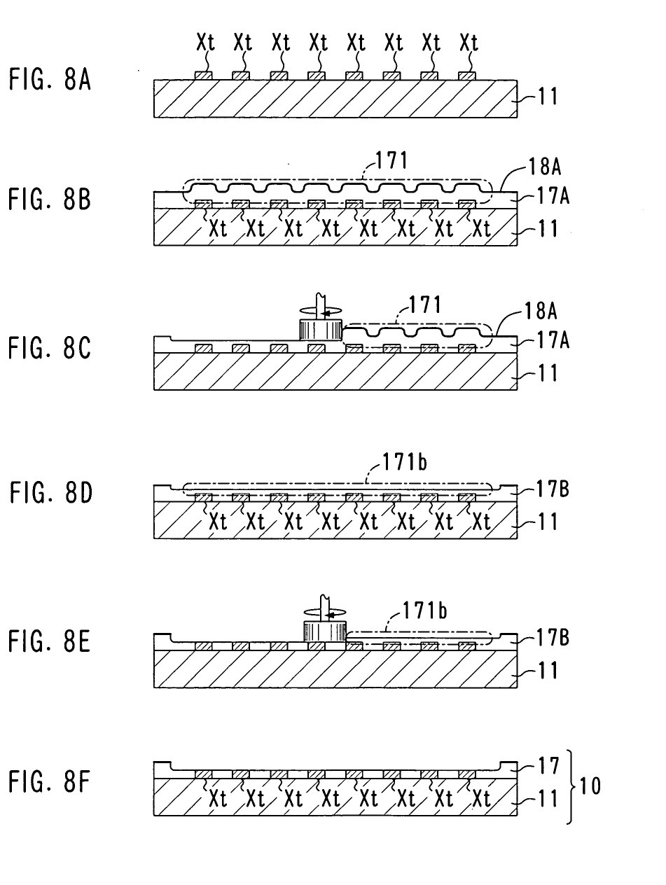

FIGS. 8(A)-8(F) show a second example of the manufacturing process of the plasma display panel.

Similarly to the first example described above, the display electrodes X and Y are formed, and further, the layer 17A made of silicon dioxide that is a dielectric and the film 18A made of magnesia that is a protection film material are formed (as shown in FIGS. 8(A) and 8(B)).

In this second example, a mechanical polishing method and the chemical mechanical polishing method are both used for the partial removal of the layer 17A and the film 18A. Namely, the portion 171 of the layer 17A that is formed by the vapor deposition method for covering the terminal portions of the display electrodes are thinned by the mechanical polishing (FIGS. 8(C) and 8(D)), and then a thin remainder 171b of the portion 171 is removed by the chemical mechanical polishing method (FIGS. 8(E) and 8(F)).

For the mechanical polishing, a fixed abrasive grain type device that rotates a moving member for polishing was used. The conditions of rotation speed at 50 rpm and working pressure at 400 g/cm² were adopted, and the polishing rate was 1000 nm/min. The mechanical polishing was used until a thickness of the portion 171 was reduced from 10 μm to 1 μm, and a remaining thickness of 1 μm is polished by the chemical mechanical polishing under the same condition as the first example. A finish timing of the mechanical polishing is determined by a time control, while a finish timing of the chemical mechanical polishing is determined by monitoring a torque change of rotation force so as to detect a finish point.

About 12 minutes were necessary for polishing to remove a thickness of 10 μm. By performing the mechanical polishing step prior to the chemical mechanical polishing step, a process time could be reduced compared with the case where only the chemical mechanical polishing step was used for polishing.

### EXAMPLE 3

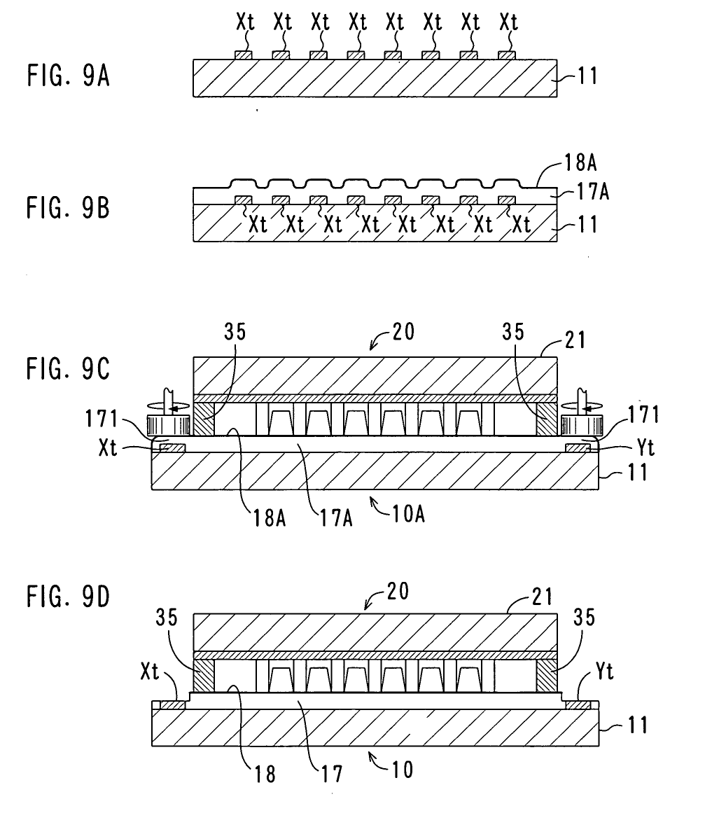

FIGS. 9(A)-9(D) show a third example of the manufacturing process of the plasma display panel. Note that a direction of cross sections in FIGS. 9(C) and 9(D) is different from that in FIGS. 9(A) and 9(B) by 90 degrees. FIGS. 9(A) and 9(B) are schematic diagrams of cross sectional structures along the vertical direction of the screen, while FIGS. 9(C) and 9(D) are schematic diagrams of cross sectional structures along the horizontal direction of the screen.

Similarly to the first example described above, the display electrodes X and Y are formed, and further, the layer 17A made of silicon dioxide that is a dielectric and the film 18A made of magnesia that is a protection film material are formed (as shown in FIGS. 9(A) and 9(B)).

In this third example, the partial removal of the layer 17A and the film 18A is preformed after the back plate 20 is glued to the front plate 10A in the state where the terminal portions Xt and Yt are not exposed. The gluing step is performed by placing the back glass substrate 21 (upper substrate in FIGS. 9(C) and 9(D)) and the front glass substrate 11 (lower substrate in FIGS. 9(C) and 9(D)) so as to face each other so that the glass substrate 21 does not cover the terminal portions Xt and Yt of the glass substrate 11. Then, the portion 171 of the layer 17A covering the terminal portions Xt and Yt is removed by using the chemical mechanical polishing method or by using both the mechanical polishing method and the chemical mechanical polishing method (as shown in FIGS. 9(C) and 9(D)). Polishing conditions are the same as the first and the second examples.

When the portion 171 is removed, the front plate 10 is completed, and then the plasma display panel 1 is completed after a step of filling discharge gas.

### EXAMPLE 4

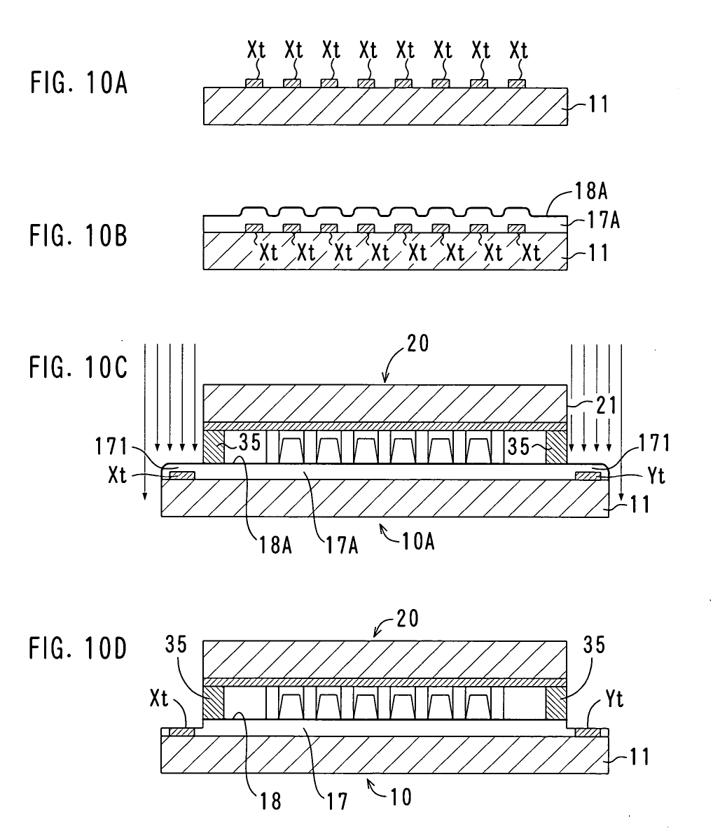

FIGS. 10(A)-10(D) show a fourth example of the manufacturing process of the plasma display panel. It should be noted here too that a direction of cross sections in FIGS. 10(A) and 10(B) is different from that in FIGS. 10(C) and 10(D) by 90 degrees.

This fourth example is similar to the third example in that the terminal portions Xt and Yt of the display electrodes are exposed after the front plate 10A is glued to the back plate 20.

Similarly to the first example described above, the display electrodes X and Y are formed (as shown in FIG. 10(A)), and the layer 17A made of silicon dioxide and the film 18A made of magnesia are formed (as shown in FIG. 10(B)). Then, the single front plate 10A obtained by dividing the mother glass is glued to the back plate 20. These steps are the same as the third example.

In this fourth example, a plasma etching method that is one type of dry etching is used as means for exposing the terminal portions Xt and Yt.

In the first through fourth examples described above, various conditions including a material of the dielectric, a condition of deposition and a condition of polishing can be changed. For example, it is possible to form the dielectric layer made of organic silicon oxide by the vapor deposition method. As the abrasive material for the chemical mechanical polishing, a mixture of ceria and silica or an alkali solution in which silica is dispersed can be used. The abrasive material for the mechanical polishing method may be aluminum oxide, chrome oxide or sodium oxide. A method of detecting exposure of the terminal portion optically may be used for detecting the finish point of polishing. A thickness of the dielectric may be measured in another method.

The finish timing of the polishing is not necessarily the timing when the terminal portions Xt and Yt are exposed. As long as selectivity of polishing is good so that the terminal portions Xt and Yt are not damaged seriously, it is possible to continue the polishing until the glass substrate 11 is exposed without any trouble in electric connection. Namely, if the polishing rate of the dielectric is larger than the polishing rate of the terminal portion, and the larger the difference between them is, the less strict the accuracy that is required for detecting the finish point of polishing is.

It is possible to use a sliding type moving member instead of the rotating type moving member for polishing. A plurality of moving members may be used for polishing plural portions simultaneously so that the process time can be reduced.

The present invention can contribute to establishing a novel process for manufacturing plasma display panels in which a vapor deposition method is used positively for forming a dielectric layer.

While example embodiments of the present invention have been shown and described, it will be understood that the present invention is not limited thereto, and that various changes and modifications may be made by those skilled in the art without departing from the scope of the invention as set forth in the appended claims and their equivalents.

What is claimed is:

1. A method for manufacturing a plasma display panel including electrodes having terminal portions at their ends and a dielectric for covering the electrodes, the method comprising the steps of:
forming a dielectric layer that covers the electrodes over the entire length thereof by a vapor deposition method on a substrate on which the electrodes are arranged; and
removing a portion of the dielectric layer formed by the vapor deposition method that covers the terminal portions of the electrodes by a polishing method.

2. The method according to claim 1, wherein the portion of the dielectric layer formed by the vapor deposition method that covers the terminal portions of the electrodes is removed by a polishing method in which a polishing rate of the portion is larger than that of the terminal portion.

3. The method according to claim 1, wherein
the portion of the dielectric layer formed by the vapor deposition method that covers the terminal portions of the electrodes is removed by a chemical mechanical polishing method.

4. The method according to claim 1, wherein
the portion of the dielectric layer formed by the vapor deposition method that covers the terminal portions of the electrodes is thinned by a mechanical polishing method, and
the thinned remaining portion is removed by a chemical mechanical polishing method.

5. A method for manufacturing a plasma display panel including electrodes having terminal portions at their ends and a dielectric for covering the electrodes, the method comprising the steps of:
forming a dielectric layer that covers the electrodes over the entire length thereof by a vapor deposition method on a first substrate on which the electrodes are arranged;
placing a second substrate to face the first substrate so that the second substrate does not cover the terminal portions of the electrodes, and gluing them to each other; and
removing a portion of the dielectric layer formed by the vapor deposition method that covers the terminal portions of the electrodes by a polishing method.

6. The method according to claim 5, wherein the portion of the dielectric layer formed by the vapor deposition method that covers the terminal portions of the electrodes is removed by a polishing method in which a polishing rate of the portion is larger than that of the terminal portion.

7. The method according to claim 5, wherein the portion of the dielectric layer formed by the vapor deposition method that covers the terminal portions of the electrodes is removed by a chemical mechanical polishing method.

8. The method according to claim 5, wherein the portion of the dielectric layer formed by the vapor deposition method that covers the terminal portions of the electrodes is thinned by a mechanical polishing method and the thinned remaining portion is removed by a chemical mechanical polishing method.

9. A method for manufacturing a plasma display panel including electrodes having terminal portions at their ends and a dielectric for covering the electrodes, the method comprising the steps of:
forming a dielectric layer that covers the electrodes over the entire length thereof by a vapor deposition method on a first substrate on which the electrodes are arranged;
placing a second substrate to face the first substrate so that the second substrate does not cover the terminal portions of the electrodes, and gluing them to each other; and
removing a portion of the dielectric layer formed by the vapor deposition method that covers the terminal portions of the electrodes by a dry etching method.
